(19) United States
(12) Patent Application Publication
(10) Pub. No.: US 2009/0257529 A1
(43) Pub. Date: Oct. 15, 2009

(54) LOW POWER, INTEGRATED RADIO TRANSMITTER AND RECEIVER

(75) Inventors: Peter Popplewell, Ottawa (CA); Victor Karam, Ottawa (CA); Calvin Plett, Ottawa (CA); John Rogers, Ottawa (CA)

Correspondence Address: SMART & BIGGAR;P.O. BOX 2999, STATION D, 900-55 METCALFE STREET, OTTAWA, ON, K1P 5Y6, CA

(73) Assignees: PETER POPPLEWELL, OTTAWA, ON (CA); VICTOR KARAM, OTTAWA, ON (CA)

(21) Appl. No.: 12/301,388

(22) PCT Filed: Mar. 5, 2007
(86) PCT No.: PCT/CA07/00340

§ 371 Date: Nov. 18, 2008

(30) Foreign Application Priority Data
May 18, 2006 (CA) 2,547,372

(51) Int. Cl. H03D 1/24

(52) U.S. Cl. 375/320

(57) ABSTRACT

A low power (optionally, self-powered) integrated transceiver using on-chip antennas is provided. The transmitter and receiver utilize phase-locked loops (PLLs) which initially, in a closed-loop state, pre-tune (i.e. phase-lock) voltage controlled oscillators (VCOs) before opening the loops to allow them to transmit and receive data. The TX, in the opened-loop state, disables the loop components while (FM) modulating the VCO. The RX, in the opened-loop state, injection-locks the VCO with the incoming (FM) modulated signal while the remaining loop components serve to demodulate the signal. For both the TX and RX an integrated antenna can be used and, advantageously, the TX comprises a dual purpose inductor which functions as both an inductor in the voltage-controlled oscillator (i.e. in the resonant tank thereof) and the integrated antenna.

### FIELD OF THE INVENTION

The invention relates to the field of wireless communications transceivers and, more specifically, to a low power, integrated transmitter (TX) and a complementary receiver (RX) architecture.

### BACKGROUND OF THE INVENTION

Short range, low power and inexpensive transceivers are well suited as radio-frequency identification (RFID) tags for asset tracking and merchandise scanning. As an example, scanning of inexpensive products such as groceries would only be feasible if the cost were low enough. Similarly, medical radiation sensors are more convenient if their output is provided wirelessly and, ideally, without need for a battery since batteries typically contain elements of high atomic mass numbers which deflect radiation.

Accordingly, there is a need for an improved transmitter and receiver which provide low power consumption suitable for use in such applications. Further, there is a need for an improved transmitter and receiver which enable an option for self-powering, such as by thin film ultracapacitor and solar cell (e.g. stacked on top of the chip), for example.

### SUMMARY OF THE INVENTION

A low power (optionally, self-powered) integrated transceiver, optionally using on-chip antennas, is provided. The transmitter and receiver utilize phase-locked loops (PLLs) which initially, in a closed-loop state, pre-tune (i.e. phase-lock) voltage controlled oscillators (VCOs) before opening the loops to allow them to transmit and receive data. The TX, in the opened-loop state, disables the loop components while (FM) modulating the VCO. The RX, in the opened-loop state, injection-locks the VCO with the incoming (FM) modulated signal while the remaining loop components serve to demodulate the signal. For both the TX and RX an integrated antenna can be used and, advantageously, the TX comprises a dual purpose inductor which functions as both an inductor in the voltage-controlled oscillator and the integrated antenna.

In particular, radio frequency (RF) transmitter circuitry is configured for transmitting an output data modulated signal, with a data signal being provided as an input. A phase-locked loop (PLL) comprises a voltage-controlled oscillator (VCO). The phase-locked loop is configured for open-loop direct VCO modulation wherein the phase-locked loop, in a closed-loop state, phase-locks the voltage-controlled oscillator's output signal to a predetermined multiple of a predetermined frequency reference and holds that multiple reference signal. The loop is opened, on a timely basis, for modulation of the voltage-controlled oscillator by the data signal. Components of the phase-locked loop, other than the voltage-controlled oscillator, are disabled when the loop is open (whereby power is saved). Advantageously, the voltage-controlled oscillator may comprise an inductor operative as both an inductor in the voltage-controlled oscillator and an integrated antenna. The voltage-controlled oscillator preferably comprises a first varactor for the locking to the reference signal and a second varactor for the direct modulation thereof by the data signal.

In addition, radio frequency (RF) receiver circuitry is configured for receiving an input data modulated signal. A phase-locked loop (PLL) comprises a voltage-controlled oscillator (VCO). In a closed-loop state, the phase-locked loop phase-locks the voltage-controlled oscillator to provide a predetermined multiple reference signal of a predetermined frequency reference signal. In an opened-loop state the voltage-controlled oscillator is injection-locked by the input data modulated signal. The phase-locked loop comprises a first charge pump configured for closing and opening the phase-locked loop, and the demodulation is performed by the phase-locked loop in the opened-loop state with a second charge pump configured for outputting a demodulated data signal. The receiver circuitry, at its input, may include an integrated antenna connected to a low noise amplifier (LNA).

A transceiver comprising the transmitter and receiver may be self-powered.

### BRIEF DESCRIPTION OF THE DRAWINGS

A better understanding of the invention will be obtained by considering the detailed description below, with reference to the following drawings in which like references refer to like elements throughout:

FIGS. 1A and 1B are illustrations of exemplary antenna topologies that may be used in a transmitter and receiver in accordance with the invention, with FIG. 1A illustrating an octagonal single turn loop antenna and FIG. 1B illustrating a square single turn loop antenna;

FIG. 2 is a graph showing the inductance (L) and Q values of the exemplary antennae of FIGS. 1A and 1B;

FIG. 3 is a schematic block diagram showing components of an exemplary transmitter circuitry configured in accordance with the invention;

FIGS. 4 (a), (b) and (c) are time domain plots, and FIG. 4 (d) is a frequency domain plot, illustrating the generation of an FM signal by the transmitter circuitry of FIG. 3;

FIG. 5 is a schematic block diagram showing components of exemplary receiver circuitry configured in accordance with the invention;

FIG. 6 is a schematic circuit diagram of the coupled LNA and VCO components of the receiver circuitry of FIG. 5;

FIG. 7 is a graph illustrating the locking bandwidth of the coupled LNA and VCO of FIG. 6;

FIG. 8 is a graph illustrating the design trade-off that can be made between the communication range and the bit rate; and,

FIG. 9 is a set of two graphs, illustrating a comparison of the TX input bitstream (the top graph) and the corresponding RX output bitstream (the bottom graph).

### DETAILED DESCRIPTION

Exemplary transceiver circuitry embodying the invention will now be described with reference to the drawings.

### (a) Integrated (i.e. On-Chip) Inductor/Antenna

The transceiver circuitry, in the TX, incorporates an on-chip combined, dual purpose, antenna/inductor which provides advantageous elegance and economy to the design and is well suited for short range applications. In the exemplary embodiment of the TX described herein a miniature on-chip antenna/inductor is used in a standard 0.13 μm CMOS process with a low resistivity silicon substrate. The same antenna design is used in both the TX and the RX for a communication range of 4.5 cm in air. In the TX, the antenna 10 is dual purpose, whereby in addition to being an integrated antenna, it operates as the oscillator inductor (i.e. in the VCO resonant tank) and, thus, there is a design tradeoff between high Q for the inductor and an appropriate radiation pattern and good efficiency for the antenna. As with any antenna design, the radiation resistance (Rᵣ) should be maximized while the loss resistance (R_{L}) should be minimized.

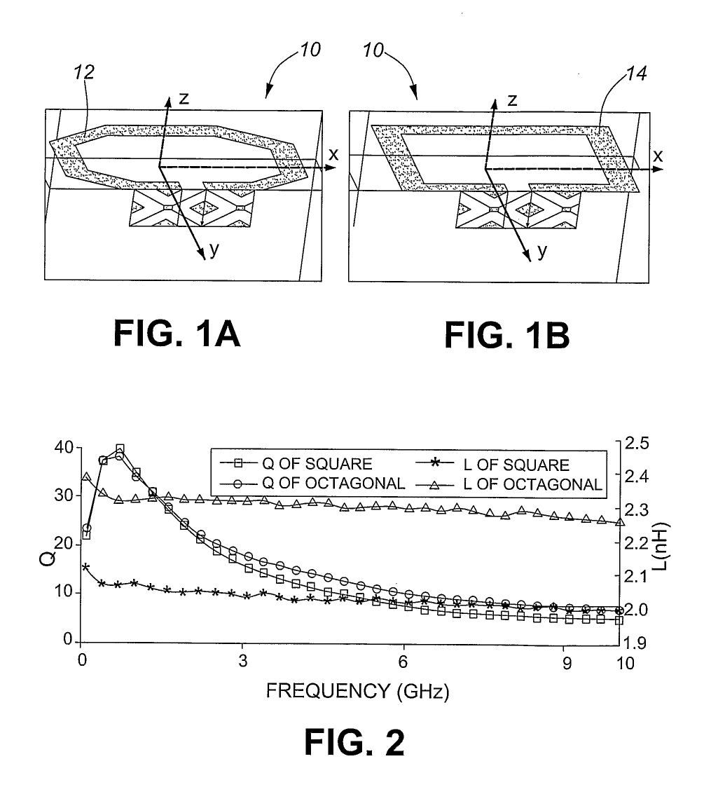

The antenna 10 topology chosen for the exemplary embodiment is a large single turn loop, leaving room inside for the TX or RX active circuitry. Optionally, an octagonal loop 12 may be used as shown in FIG. 1A or, a square loop 14 may be used as shown in FIG. 1B, the latter being used in the embodiment described herein. The inductance and Q versus frequency for each such alternative, in exemplary embodiments, are shown in FIG. 2.

Both such antennas, described here as examples only, have an outer diameter of 1 mm, metal width of 0.1 mm, a feeding gap of 0.1 mm, and are fed differentially. Although the octagonal loop 12 may be preferable for an on-chip inductor, the square loop 14 is more suitable as an on-chip antenna/inductor because it provides greater gain (e.g. −22 dB versus −23 dB in the exemplary embodiment) because the 90° bends cause Rᵣ to increase, resulting in reduced Q but increased gain. Both antennas 10 display desirable, smooth, omni-directional radiation patterns in the x-y plane and a broad double lobe pattern in the elevation plane with the null on the chip edges. Advantageously, these gains were achieved without the use of a patterned ground plane which is a typical method of improving the Q and inductance, but one that decreases the antenna gain considerably.

The effectiveness of an antenna can be measured by the antenna's efficiency (ρ_{A}), which is the ratio of radiated power to total power dissipated by the antenna, calculated as ρ_{A}=Rᵣ/(R_{L}+Rᵣ). The differential impedance of the exemplary square inductor at 5.2 GHz is Zin=7.12+j66.00Ω, and thus Rᵣ+R_{L}=7.12Ω. The efficiency is ρ_{A}=0.67, and thus Rᵣ=4.77Ω and R_{L}=2.34Ω. As will be understood by the skilled reader the necessary signal levels for the TX and RX can then be readily calculated given these known parameters of the antenna.

### (b) System Link Budget And the Friis Equation

Assuming conjugate matching to the antennas, the link budget is found using the Friis equation, as set forth in the following as equation (1) (this relationship being known to persons skilled in the art):

P_{R}=P_{T}G_{T}G_{R}(λ_{O}/4πr)² (1)

where P_{R}, P_{T}, G_{T} and G_{R} are the powers and gains of the RX and TX antennas respectively, λ_{O} is the signal's wavelength in free space (λ_{O}≈57.5 mm at 5.2 GHz, for example), and r is the distance between the two antennas. Since the same antenna may be used for both the TX and the RX, G_{T}=G_{R}=−22 dB. The peak-to-peak signal swing at the terminals of the transmitting antenna is 2.0 V, and thus the transmitted power can be calculated as P_{T}=564 μW. Using the Friis equation (1) for a separation of 4.5 cm for example, P_{R}=235.5 pW which yields a peak-to-peak signal swing of V_{R}=115.8 μV at the output of the receive antenna with a conjugately matched load. Thus, the receiver topology is configured so as to be sensitive enough to handle this signal level.

### (c) Transmitter

### Circuit Topology

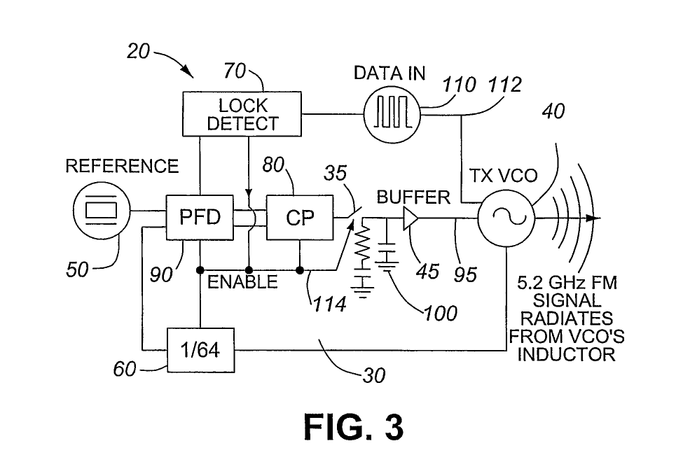

It is known to design transmitters using a closed-loop PLL directly modulated via the VCO control input, or via the divider through a Sigma-Delta (ΣΔ) controller. Advantageously, the exemplary TX 20 described herein, uses open-loop direct VCO modulation as shown in FIG. 3. With no PLL feedback, the VCO's output frequency is vulnerable to pulling but the frequency drift can be minimal at 2.5 Hz/μs for a low-voltage VCO in the present modern semiconductor process.

In operation, initially the TX 20 is powered up and the PLL 30 locks the VCO 40 to a multiple of the reference 50. In this embodiment, the reference signal is at 81.25 MHz and the VCO is locked to 5.2 GHZ, or 64 times the reference. For reduced power consumption, six fixed divide-by-two prescalers are cascaded to form the divider 60 instead of a multimodulus divider (MMD) design (it is to be noted that channel selection would require a MMD or the use of different reference frequencies). Once phase-locked, a lock detection circuit 70 triggers the loop to open, disabling a charge pump (CP) 80, a phase-frequency detector (PFD) 90, and the divider 60, while the necessary control voltage 95 for a VCO frequency of 5.2 GHz is held on the loop filter 100. As shown by FIG. 3, a switch 35 opens the loop and a buffer 45 prevents any bleeding of the charge through the VCO (i.e. as will be known by the skilled reader, such bleeding would undesirably cause the frequency to drift). The digital bitstream containing the input data 110 is switched onto a second VCO control line 112, which controls a second varactor (not shown) to modulate the VCO spectrum using BFSK FM according to the data packet to be transmitted. As stated above, the VCO inductor doubles as the antenna for the transmitter and, advantageously, no power amplifier is needed. During VCO modulation, power is conserved by turning off the PLL's divider, PFD and CP.

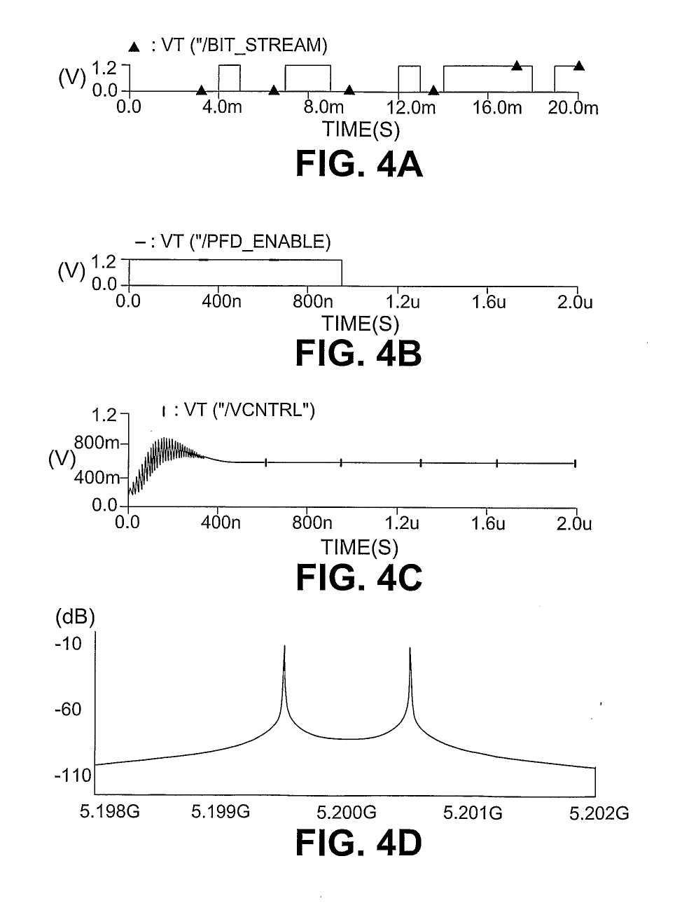

FIG. 4(a) shows the input bitstream which is applied to the second control line 112 of the VCO 40 to yield the FM modulated output of the VCO, shown in FIG. 4(d) in the frequency domain. The enable signal 114 which turns on all the PLL blocks to lock the VCO to the correct center frequency is shown in FIG. 4(b), while FIG. 4(c) shows the transient control voltage signal as the loop acquires lock. These three time domain plots show the different time scales, whereby the input bitstream is not applied until well after the loop is locked and the majority of the loop components have been disabled.

### FM Modulation

The frequency separation (Δf) of the modulated output is small enough that the VCO 200 in the receiver 25 can injection-lock to it, but wide enough that the frequency difference can be distinguished by the PFD 210 in the receiver 25. Similarly, the modulation frequency (fₘ) must be high enough to enable higher data rates, but low enough to give the PFD 210 and CP 220 in the receiver 25 enough time to deduce a 1 or a 0 bit. In the embodiment described herein Δf=500 kHz and fₘ=1 kHz. The trade-offs between fₘ, Δf and communication range are described below.

### (d) Receiver

### Oscillation Gain And Injection-Locking

It is known that LC oscillators have potential as high gain filters. If the amplitude of the injected voltage (Vᵢₙⱼ) is much smaller than that of the free-running oscillator (V_{osc}), the locking range can be approximated by Adler's equation (2), as follows:

ω_{L}≈(ωₒ/2Q_{U})(Vᵢₙⱼ/V_{osc}) (2)

where ω_{L} is the single-sided locking bandwidth, i.e. the oscillator can be locked from ωₒ−ω_{L} to ωₒ+ω_{L}.

Equation (2) suggests that the oscillator is easier to injection-lock at smaller frequency offsets from ωₒ. As a result, the oscillator functions as a narrow-band, high gain amplifier in the front end of the receiver.

### Receiver Circuit Topology

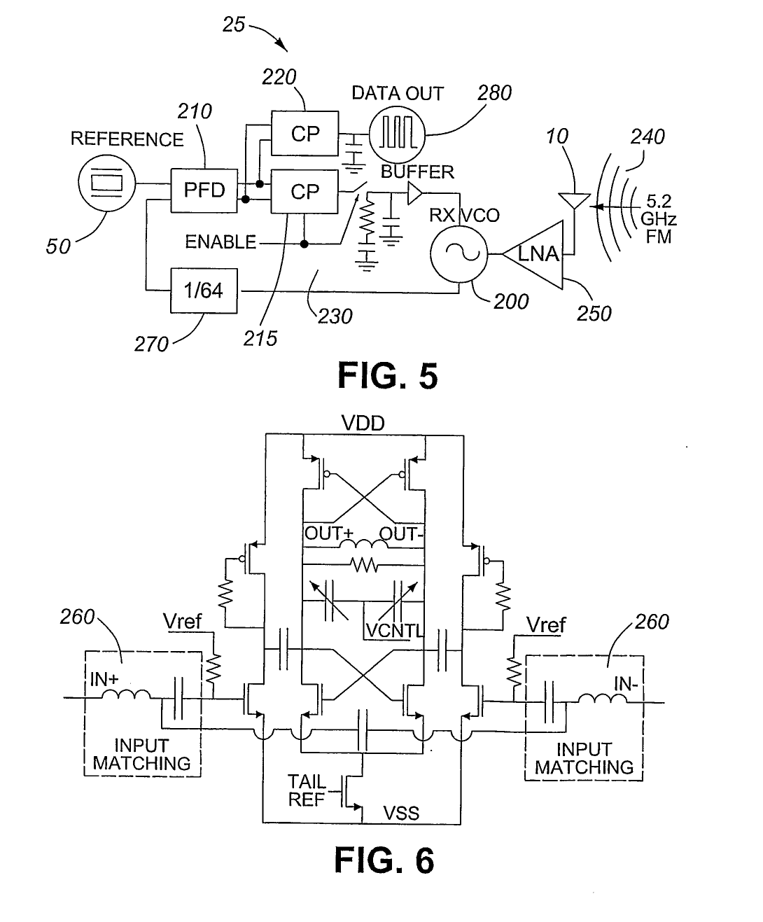

Similar to the transmitter circuit 20, the receiver circuit 25 of the exemplary embodiment shown in FIG. 5 makes use of a traditional PLL 230 where the loop is opened and closed by disabling the primary CP 230 and by opening a switch. While many of the TX 20 blocks are disabled during open-loop operation to save power, all the loop components in the RX 25 remain enabled (except for the primary CP 230) and serve as the demodulation circuit for the FM modulated input 240. A second CP 220, as shown, serves to demodulate the received bitstream based on the PFD's 210 output.

Like the TX PLL, the receiver loop 230 is initially closed to set the center frequency. The loop is then opened, and the oscillator 200 is injection-locked to the incoming FM modulated signal 240. An antenna 10, which may be on-chip, is connected to the input of a low noise amplifier (LNA) 250, which has a gain of 20 dB, and couples the FM modulated input into the initially free-running oscillator 200. When the coupled signal is strong enough and the instantaneous frequency of the FM input is within the locking bandwidth, the oscillator 200 will injection-lock to the incoming signal.

The oscillator 200, in this example, has a free-running differential peak-to-peak swing of 1.0 V and a tank inductor with Q≈5 after degeneration. As shown in respect of the illustrated embodiment of the transmitter, the FM signal bandwidth is 1 MHz (switching between 5.1995 GHz and 5.2005 Ghz). The peak-to-peak antenna output swing is 115.8 μV. With an LNA gain of 20 dB, the injected signal into the VCO will be 1.16 mV peak-to-peak. As a result, from equation (2), the locking bandwidth is f_{L}≈602 kHz. Thus, the FM modulated input is always within the locking range of the receiving oscillator.

### Receiver LNA And VCO Design

A schematic illustration of the coupled LNA 250/VCO 200 circuit in the RX 25 is shown in FIG. 6. The differential antenna and LNA are matched 260 using series inductors, a shunt capacitor and series capacitors. As a low input impedance is required, the input devices have 10 gate fingers to minimize the series gate resistance. Resistors bias the LNA appropriately while isolating the AC input from V_{ref}. The LNA output is lightly coupled to the VCO tank circuit using small capacitors, so as not to disturb the tank resonance. A tank degeneration resistor and an adjustable tail current in the VCO limit the output swing to only 1 V, enabling injection-locking as calculated above.

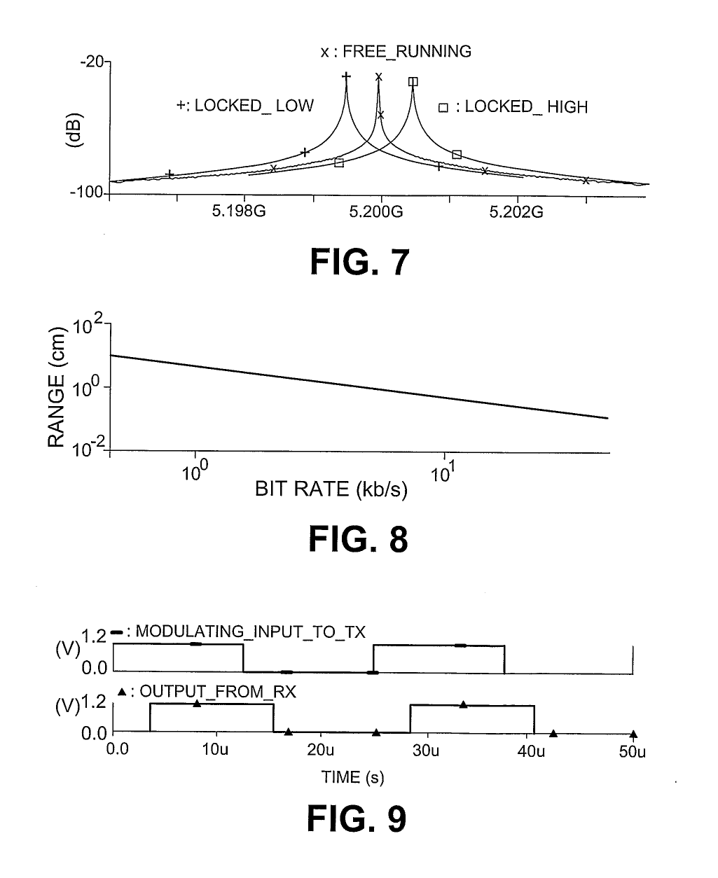

FIG. 7 shows the LNA 250/VCO 200 output with no input to the LNA, and then injection-locked to a 235.5 pW antenna output at 5.1995 Ghz and 5.2005 GHz. This verifies that the received signal level is large enough to injection-lock the VCO 200 within the required bandwidth.

### System Sensitivity

From the foregoing analysis, trade-offs can be made between inter alia communication range, antenna gains, and bit rates. Following a bit transition and the resulting frequency shift, the time required for the RX loop to demodulate is dependent on the phases of the inputs to the PFD, (F_{REF} and F_{DIV}). The worst case lock time can be shown to be inversely related to the beat frequency between F_{REF} and F_{DIV}. With an F_{REF}=81.25 MHz, a bit rate of only 1 kb/s, and a Δf=500 kHz, the maximum delay between a bit change (and corresponding frequency change) at the input to the PFD in the RX and the resulting bit change at the output of the receiver's CP is about 12% of the bit length. The beat period at the input of the PFD is given by the following equation (3):

T_{BEAT}=1/(Δf/N)=1/500 kHz/64=128 μs (3)

Increasing Δf would decrease this wait time, but as equation (2) suggests, this would require greater received power to keep the receiving VCO injection-locked. From equation (1), P_{R} can be increased with a decrease in range, or increased antenna gain.

FIG. 8 shows the trade-off that can be made between the communication range and the bit rate, assuming that Δf is adjusted with the bit rate to maintain the worst case delay at 12% of the bit length. Alternatively, the communication range could be increased at the expense of power consumption by increasing the reference frequency in the receiver.

### Receiver Behaviour

Once the RX 25 loop 230 is opened and the VCO 200 is injection-locked, the divider 270, PFD 210 and secondary CP 220 attempt to compensate for the now modulated VCO 200 by producing a control voltage that, if connected to the VCO, would counter its frequency/phase change. This voltage will be a delayed and inverted copy of the bitstream that was used in the transmitter to produce the FM modulated signal. It is to be noted that the correct output polarity, for the output data signal 280, is achieved by simply swapping the inputs to the secondary CP 220.

FIG. 9 shows the original input bitstream and the output of the secondary CP 220. The resulting output bitstream is simply a delayed version of the input.

### (e) Ultracapacitors As A Power Source

Developments in the design and manufacturing of ultracapacitors have made it possible to meet the power supply requirements of small integrated circuits without using a battery. Typical 100 μm thick nanostructured electrode devices can give up to 1 F/cm², which is sufficient charge storage to power the circuits of the embodiment described herein. In the embodiment described herein as an example, the chip measures 2 mm by 2 mm of which the integrated antenna and the RX/TX circuitry occupy one quarter. This allows for three 1 mm by 1 mm ultracapacitors (not shown) to be manufactured on top of the remaining three quadrants of the chip without covering up the antenna which would decrease its gain. This results in a 30 mF capacitance which is capable of about 4.2 μA/hr or about 15 mA for a one second burst between chargings. Standard integrated capacitors are fabricated in the regular CMOS process below the ultracapacitors and serve as local charge storage devices because they can deliver charge quicker than the ultracapacitors which recharge them.

A solar cell (not shown) may be manufactured on top of the ultracapacitors and serve to trickle charge the ultracapacitors using ambient light.

With the foregoing exemplary embodiments having been disclosed, it will be apparent to those skilled in the art that various changes and modifications can be made which will achieve the advantages of the invention all of which are intended to fall within the scope of the invention as claimed.

1-4. (canceled)

5. Radio frequency (RF) receiver circuitry for receiving an input data modulated signal, said receiver circuitry comprising a phase-locked loop (PLL) having a voltage-controlled oscillator (VCO), wherein said phase-locked loop, in a closed-loop state, phase-locks said voltage-controlled oscillator to provide a VCO output signal having a frequency that is a multiple of a frequency reference and wherein, when said phase-locked loop is in an opened-loop state, said voltage-controlled oscillator is injection-locked by said input data modulated signal.

6. Radio frequency (RF) receiver circuitry according to claim 8 wherein said antenna is an integrated antenna.

7. Radio frequency (RF) receiver circuitry according to claim 5 wherein:
said phase-locked loop comprises a first charge pump configured for closing said loop into said closed-loop state and opening said phase-locked loop into said opened-loop state;
said radio frequency (RF) receiver circuitry further comprises a second charge pump; and
said phase-locked loop, in said opened-loop state, demodulates said input data modulated signal with the second charge pump configured to output a demodulated data signal.

8. Radio frequency (RF) receiver circuitry according to claim 5 further comprising:
a low noise amplifier (LNA); and
an antenna,
wherein said (LNA) is operatively connected between said voltage-controlled oscillator and said antenna to injection-lock said voltage-controlled oscillator with said input data modulated signal received via said antenna.

9. Radio frequency (RF) receiver circuitry according to claim 5 wherein said phase-locked loop further comprises:
a charge pump configured for closing said phase-locked loop into said closed-loop state and opening said phase-locked loop into said opened-loop state;
a filter before the VCO for holding a control voltage on said VCO such that said VCO substantially maintains said frequency of said VCO output signal at said multiple of said frequency reference after said VCO is phase-locked;
a buffer between the filter and the VCO; and
a switch between said charge pump and said filter,
wherein said switch is open in said opened-loop state to provide isolation between said filter and said charge pump in the opened-loop state.

10. (canceled)

11. A wireless device comprising radio frequency (RF) receiver circuitry according to claim 5.

12. An integrated transceiver comprising:
radio frequency (RF) receiver circuitry for receiving an input data modulated signal, said receiver circuitry comprising a first phase-locked loop (PLL) having a first voltage-controlled oscillator (VCO), wherein said first phase-locked loop, in a closed-loop state, phase-locks said first voltage-controlled oscillator to provide a VCO output signal having a frequency that is a multiple of a first frequency reference and wherein, when said first phase-locked loop is in an opened-loop state, said first voltage-controlled oscillator is injection-locked by said input data modulated signal; and
radio frequency (RF) transmitter circuitry for transmitting an output data modulated signal, said transmitter circuitry comprising a second phase-locked loop (PLL) having a second voltage-controlled oscillator (VCO) and configured for open-loop direct VCO modulation, wherein said second phase-locked loop, in a closed-loop state, phase-locks said second voltage-controlled oscillator to provide a VCO output signal having a frequency that is a multiple of a second frequency reference and wherein, when said second phase-locked loop is in an opened-loop state, said second phase-locked loop is configured for modulation of said second voltage-controlled oscillator by a data signal to generate said output data modulated signal, wherein one or more components of said second phase-locked loop, other than said second voltage-controlled oscillator, are disabled to save power when said second phase-locked loop is in said opened-loop state.

13. The integrated transceiver according to claim 12 further comprising:
a low noise amplifier (LNA); and
an antenna,
wherein said LNA is operatively connected between said first voltage-controlled oscillator and said antenna to injection-lock said first voltage-controlled oscillator with said input data modulated signal received via said antenna.

14. The integrated transceiver according to claim 12 wherein:
said first phase-locked loop comprises a first charge pump configured for closing said first phase-locked loop into said closed-loop state and opening said first phase-locked loop into said opened-loop state;
said radio frequency (RF) receiver circuitry further comprises a second charge pump; and
said first phase-locked loop, in said opened-loop state, demodulates said input data modulated signal with the second charge pump configured to output a demodulated data signal.

15. The integrated transceiver according to claim 13 wherein said antenna is an integrated antenna.

16. The integrated transceiver according to claim 12 wherein said first phase-locked loop further comprises:
a charge pump configured for closing said first phase-locked loop into said closed-loop state and opening said first phase-locked loop into said opened-loop state;
a filter before the first VCO for holding a control voltage on said first VCO such that said first VCO substantially maintains said frequency of said first VCO output signal at said multiple of said first frequency reference after said first VCO is phase-locked;
a buffer between said filter and said first VCO; and
a switch between said charge pump and said filter,
wherein said switch is open in said opened-loop state of said first phase-locked loop to provide isolation between said filter and said charge pump in the opened-loop state.

17. The integrated transceiver according to claim 12, wherein the first and second phase-locked loops share one or more of the following loop elements:
a charge pump (CP) configured for opening said loops into said opened-loop states and closing said loops into said closed-loop states;
a filter before the first VCO and the second VCO;
a switch configured to provide isolation between said charge pump and said filter in said opened-loop states;
a divider configured for dividing said frequency of said first VCO output signal by said multiple of said first frequency reference and dividing said frequency of said second VCO output signal by said multiple of said second frequency reference;
a phase-frequency detector (PFD) between said divider and said charge pump;
a shared frequency reference such that said first and second frequency reference are the same; and
an antenna configured for receiving said input data modulated signal and transmitting said output data modulated signal.

18. The integrated transceiver according to claim 12, wherein said second VCO comprises an inductor operative as both an inductor in said second VCO and as an integrated antenna.

19. The integrated transceiver according to claim 12, wherein said second VCO comprises a first varactor for said phase-locking to said second frequency reference and a second varactor for said direct modulation thereof by said data signal.

20. The integrated transceiver according to claim 12, wherein said second PLL comprises:
a charge pump configured for closing said second phase-locked loop into said closed-loop state and opening said second phase-locked loop into said opened-loop state;
a filter before the second VCO for holding a control voltage on said second VCO such that said second VCO substantially maintains said frequency of said second VCO output signal at said multiple of said second frequency reference after said second VCO is phase-locked;
a buffer between said filter and said second VCO; and
a switch between said charge pump and said filter,
wherein said switch is open in said opened-loop state of said second phase-locked loop to provide isolation between said filter and said charge pump in the opened-loop state.

21. The integrated transceiver according to claim 12, wherein the integrated transceiver is self-powered.

22. A wireless device comprising the integrated transceiver according to claim 12.

23. A method comprising:
alternating between a closed-loop state and an opened-loop state of a first phase-locked loop comprising a first voltage-controlled oscillator;
in a closed-loop state of the first phase-locked loop, phase-locking said first voltage-controlled oscillator to provide a first VCO output signal having a frequency that is a multiple of a first frequency reference; and
in the opened-loop state of the first phase-locked loop:
receiving an input data modulated signal; and
injection-locking said first voltage-controlled oscillator with said input data modulated signal.

24. The method according to claim 23 further comprising:
in the opened-loop state of the first phase-locked loop, demodulating said input data modulated signal with said first phase-locked loop.

25. The method according to claim 23 further comprising:
alternating between a closed-loop state and an opened-loop state of a second phase-locked loop comprising a second voltage-controlled oscillator;
in the closed-loop state of the second phase-locked loop, phase-locking said second voltage-controlled oscillator to provide a second VCO output signal having a frequency that is a multiple of a second frequency reference; and
in the opened-loop state of the second phase-locked loop:
disabling one or more components of said second phase-locked loop, other than said second voltage-controlled oscillator to save power in the opened-loop state;
directly modulating said second voltage-controlled oscillator with a data signal to generate an output data modulated signal; and
transmitting said output data modulated signal.
